(19) United States
(12) Patent Application Publication
(10) Pub. No.: US 2010/0226080 A1
(43) Pub. Date: Sep. 9, 2010

(54) SLIDE DEVICE AND ELECTRONIC DEVICE USING SLIDE DEVICE

(76) Inventors: Takashi Tsuchida, Tokyo (JP); Noriaki Kubota, Tokyo (JP)

Correspondence Address: Kubotera & Associates, LLC, 200 Daingerfield Rd, Suite 202, Alexandria, VA, 22314, US

(21) Appl. No.: 12/682,982

(22) PCT Filed: Oct. 24, 2008
(86) PCT No.: PCT/JP2008/069822

§ 371 Date: Apr. 14, 2010

(30) Foreign Application Priority Data
Oct. 26, 2007 (JP) 2007-279700
Jan. 8, 2008 (JP) 2008-001309

(51) Int. Cl. H05K 7/00; F16C 29/02

(52) U.S. Cl. 361/679.01; 384/42

(57) ABSTRACT

The invention provides a slide device where a slide part 2 of a second member B is slidably engaged between slide guide portions 1 of a first member A. The slide device includes protrusions 5 that have a height where slidable engagement may not be achieved, and the protrusions 5 are crushed so as to have a predetermined height, so that the slide part may be slidably engaged between the slide guide portions. Further, the invention provides a slide device. The slide device includes guide rail portions 23 that are provided at a first member 21 or a second member 22, slide portions 25 that are provided at the second member 22 or the first member 21 and relatively move along the guide rail portions 23, and a biasing body 27 which is disposed between the first and second members 21 and 22 and of which one end is connected to the first member 21 and the other end is connected to the second member 22 so as to make the second member 22 move relative to the first member 21 in a slide direction. Furthermore, the invention provides an electronic device using the slide device.

### TECHNICAL FIELD

The present invention relates to a slide device that forms a slide structure used for a general device or an electronic device such as a mobile phone, and a device using the slide device.

### BACKGROUND ART

For example, there is known a slide type mobile phone where an operation portion where numeric keys and function keys are arranged is provided on an upper surface of a main body, a display such as a liquid crystal panel, which makes a predetermined display, is provided on an upper surface of an overlapping part that overlaps with the main body, and the main body and the overlapping part move forward and backward relative to each other. In this kind of slide type mobile phone, guide rail portions as slide guide portions are provided on left and right sides of the overlapping part with a distance therebetween, a slide part, which is slidably engaged with the left and right guide rail portions, is provided at the main body, and the slide part slides relative to the guide rail portions. Accordingly, the overlapping part and the main body are slidably connected to each other.

According to the slide type mobile phone, even though the overlapping part is not opened (rotated) with respect to a main body, it may be possible to see the display displayed on the display unlike a folder type mobile phone while the overlapping part overlaps with the main body. Further, when it is intended to operate the numeric keys or the function keys of the operation portion, it may be possible to expose the operation portion to the outside merely by slidably moving the overlapping part relative to the main body, and to easily operate the keys.

A slide device, which is used to achieve the slide device, is formed so that the slide part is slidably engaged with the slide guide portions while the both end portions of the slide part are slidably engaged between the slide guide portions provided on left and right sides as described above.

For example, two guide rail portions are disposed at a first member of one member (first member) and the other member (second member), which are to be slidably engaged with each other, so as to face each other, and a slide part, which includes slidable engagement portions at both ends thereof, is provided at the second member. The slidable engagement portions, which are provided at both ends of the slide part, are slidably engaged with the slide guide portions of the first member, so that the slide part is slidably engaged between the slide guide portions. Accordingly, the second member is slidably engaged with the first member. Further, the slidable engagement portions, which are slidably engaged with the respective guide rail portions, may be provided at both ends, and the second member may be used as the slide part.

In any case, concavity or convexity of a convexo-concave relationship of the slidable engagement may be formed at any portion in a slide device that smoothly and stably connects two members so as to allow the two members to slide. However, the slide part is slidably engaged between the slide guide portions.

For this purpose, the slide device requires clearance for engagement, and there is also a limit to the manufacturing accuracy of components. Accordingly, looseness is necessarily generated.

That is, since the slide part should be necessarily inserted between the slide guide portions, the slide part has looseness due to the limit to the clearance and manufacturing accuracy. For this reason, if the slide part does not smoothly slide or an external force is applied to the slide device, the slide part is twisted due to the looseness, so that the smooth slide is obstructed. As a result, there are various problems in that the slide part is broken or durability deteriorates and sliding sound is apt to be generated.

Further, even if the clearance is made as much close to zero as possible through the improvement of manufacturing accuracy (dimension accuracy) in order to avoid these, variation in dimension could be generated in the case of parts of another lots. Accordingly, the slide part is not slidably engaged in this case or, conversely, further looseness could be generated. For this reason, even if the variation of parts is made close to zero through the improvement of manufacturing accuracy, various kinds of parts having different dimensions should be prepared in order to make another parts, which are manufactured as another lots, be slidably engaged without looseness.

Furthermore, until now, some looseness cannot be prevented due to engagement clearance, the limit to manufacturing accuracy, or variation in the accuracy of different products. However, a first invention is to change the way of thinking by doing away with the stereotypes. That is, if protrusions are merely formed, first, slidable engagement may not be achieved by the protrusions. The protrusions are crushed so as to have a height where slidable engagement may be achieved, so that a part to be slidably engaged (for example, a slide part with respect to the slide guide portion) may be slidably engaged. Even if the manufacturing accuracy of parts deteriorates and variation occurs for every part, it may be possible to easily achieve a slide device having small looseness, which always corresponds to clearance close to zero in accordance with the crushed condition of the protrusions, by crushing the protrusions according to the variation. Further, if there is no variation on products having high manufacturing accuracy and an appropriate crushed amount or the height of the crushed protrusion is set once, it may be possible to easily mass-produce slide devices without looseness by uniformly crushing the protrusions so that the protrusions have the preset height. Furthermore, even when parts of other lots are used, it may be possible to easily change the setting by crushing the protrusions again so that the protrusions have a height where slidable engagement may be achieved. An object of the invention is to always provide a slide device without looseness, and to provide a slide device that can achieve a slide structure, which hardly has looseness, by simple modification and simple operation, and a device using the slide device.

Meanwhile, due to the structure of a slide device in the related art, particularly, a sliding surface 53a of one (right) guide rail portion 53 and a sliding surface 55a of a slide part 55 come into pressure contact with each other and slide with each other with biasing of a biasing body when first and second connection bodies move relative to each other in a slide direction due to biasing made by the biasing body. Accordingly, large frictional resistance is generated, so that good (smooth) slide is hardly performed (see FIG. 26).

Even though a spring force is increased for the increase of the momentum of the slide, frictional resistance is increased correspondingly. Accordingly, good slide is hardly performed and cost is increased. For this reason, the increase of the spring force does not become a decisive countermeasure. Further, if a material having small frictional resistance between the sliding surfaces is used, cost is increased. In addition to this, a method of applying grease on the sliding portion has been tried as a method of reducing the frictional resistance between the sliding surfaces. However, there are concerns that a user makes leaked grease enter a mouth or eyes by mistake in addition to problems, such as the deterioration of appearance caused by a grease leak, the deterioration of handleability at the time of assembling, and the adhesion of grease to electrical components.

The inventor had noted the above-mentioned problems, and repeatedly performed various experimental studies. As a result, the inventor has developed a slide device exhibiting operation and effects that have not been obtained in the past, and an electronic device using the slide device.

### DISCLOSURE OF THE INVENTION

The gist of a first invention will be described with reference to drawings.

An invention according to claim 1, there is provided a slide device for connecting a first member with a second member so that the second member B is slidable relative to the first member A when a slide part 2 of the second member B (that is, a slide part 2 provided at the second member B or provided as the second member B) is slidably engaged between slide guide portions 1 of the first member A (that is, slide guide portions 1 provided at the first member A or provided as the first member A), wherein protrusions 5, which have a height where the slide part 2 may not be slidably engaged between the slide guide portions 1, are formed on the slide guide portions 1 or slide surfaces 3 of the slide part 2 or on portions that exclude the slide guide portions 1 or slide surfaces 3 of the slide part 2 and determine the positions of the slide surfaces 3, and the slide part 2 is slidably engaged between the slide guide portions 1 by crushing the protrusions 5 to a predetermined height.

Further, an invention according to claim 2, in the slide device according to claim 1, protrusions 5, which have a height where the slide part 2 may not be slidably engaged between the slide guide portions 1, are formed on the slide guide portions 1 or the slide surfaces 3 of components 4 of the slide part 2, or on portions that exclude the slide surfaces 3 of the components 4, are positioned between the components 4, and determine the positions of the slide surfaces 3.

Furthermore, an invention according to claim 3, in the slide device according to claim 1 or 2, the protrusions 5 are crushed so as to have a height where the slide part 2 may be slidably engaged between the slide guide portions 1.

Moreover, an invention according to claim 4, in the slide device according to any one of claims 1 to 3, the protrusions 5 are formed on at least both end portions of a slide range of the slide part 2 with respect to the slide guide portions 1.

Further, an invention according to claim 5, in the slide device according to any one of claims 1 to 4, the protrusions 5 protrude in a rounded and protruding shape.

Furthermore, an invention according to claim 6, there is provided a device using the slide device according to any one of claims 1 to 5 where a main body and an overlapping part are disposed to overlap with each other, the main body and the overlapping part are connected to each other by a slide device so that the overlapping part slides so as to relatively pass in a direction of an overlapping surface from a state where the main body and the overlapping part overlap with each other and a part of the overlapping surface is exposed to the outside, and the main body is formed of the first member or the second member and the overlapping part is formed of the second member or the first member in the slide device.

From the above-mentioned structure, the first invention may easily achieve a slide device having small looseness, which always corresponds to clearance close to zero, by crushing the protrusions so that the protrusions have a height where the slide part may be slidably engaged between the slide guide portions. Further, if there is no variation in products having high manufacturing accuracy and a crushed amount or the height of the crushed protrusion is set once, it may be possible to easily mass-produce slide devices without looseness by uniformly crushing the protrusions so that the protrusions have this height. Furthermore, even when parts of other lots are used, it may be possible to easily change the setting by crushing the protrusions again so that the protrusions have a height where slidable engagement may be achieved, and to always provide a slide device without looseness.

That is, the first invention provides a slide device that can achieve a slide structure, which hardly has looseness, by simple modification and simple operation, and a device using the slide device.

Further, in the invention of claim 2, the slide guide portions or the slide part may be formed by providing components that are interposed and form the slide surfaces so as to make slide better. In this case, the protrusions may be directly formed on the slide surfaces of the slide surface forming member, and may be formed on the sides opposite to the slide surfaces where the slide surface forming members are assembled. The protrusions may be formed on another component for receiving the component, so that the positions of the slide surfaces are adjusted by the adjustment of the height of each protrusion. In any case, since protrusions are formed on the components in the invention, there is obtained an excellent slide device that may easily achieve smooth slide and more easily performs the formation of the protrusions or a crushing operation.

Furthermore, in the inventions of claims 3 to 5, there is obtained an excellent slide device that provides the better operation and effects.

Moreover, in the invention of claim 6, there is obtained a slide device that is very excellent in practicality and may reliably provide the above-mentioned operation and effects well.

The gist of a second invention will be described below with reference to drawings.

According to an invention of claim 7, there is provided a slide device that slidably connects a first member 1 and a second member 2 disposed to overlap with the first member 1. The slide device includes guide rail portions 3 that are provided at the first member 1 or the second member 2, slide portions 5 that are provided at the second member 2 or the first member 1 and relatively move along the guide rail portions 3, and a biasing body 7 which is disposed between the first and second members 1 and 2 and of which one end is connected to the first member 1 and the other end is connected to the second member 2 so as to apply a biasing force to the second member 2 to move relative to the first member 1 in a slide direction. The slide device includes a frictional resistance reducing member that is formed by providing a concave portion 10, which does not come into contact with the other sliding surface, on at least one sliding surface of the sliding surfaces of the guide rail portion 3 and the slide portion 5, which come into pressure contact with each other and slide with each other, with the biasing force of the biasing body 7 when the first and second members 1 and 2 move relative to each other in the slide direction due to the biasing force of the biasing body 7, the frictional resistance reducing member reducing frictional resistance between the sliding surfaces through the reduction in contact area.

Further, according to an invention of claim 8, in the slide device according to claim 7, the concave or convex guide rail portions 3 are provided at the first member 1 or the second member 2. The convex or concave slide portions 5 engaged with the guide rail portions 3 are provided at the second member 2 or the first member 1. The frictional resistance reducing member is formed by providing a concave portion 10, which does not come into contact with the other sliding surface, on at least one sliding surface of a convex end sliding surface 9a that is positioned at the end of the convex slide portion 5 or the convex guide rail portion 3, and a sliding surface 8a of the concave guide rail portion 3 or the concave slide portion 5 with which the convex end sliding surface 9a comes into pressure contact and slides with the biasing force of the biasing body 7.

Furthermore, according to an invention of claim 9, in the slide device according to claim 7 or 8, the concave or convex guide rail portions 3 are provided at the first member 1 or the second member 2. The convex or concave slide portions 5 engaged with the guide rail portions 3 are provided at the second member 2 or the first member 1. The frictional resistance reducing member is formed by providing a concave portion 10, which does not come into contact with the other sliding surface, on at least one sliding surface of a convex side end sliding surface 9b that is positioned at the side end of the convex slide portion 5 or the convex guide rail portion 3, and a sliding surface 8b of the concave guide rail portion 3 or the concave slide portion 5 with which the convex side end sliding surface 9b comes into pressure contact and slides with the biasing force of the biasing body 7.

Moreover, according to an invention of claim 10, in the slide device according to any one of claims 7 to 9, the concave guide rail portion 3 or the concave slide portion 5 is formed by providing a U-shaped body 11, which includes a groove 11a, at an end portion of a first connection body 4 that is formed of a plate connected to the first member 1 or the second member 2. The convex slide portion 5 or the convex guide rail portion 3, which is engaged with the concave guide rail portion 3 or the concave slide portion 5, is provided with an end portion of a second connection body 6 that is formed of a plate connected to the second member 2 or the first member 1. The frictional resistance reducing member is formed by providing the concave portion 10 on an inner surface of the groove 11a of the U-shaped body 11.

Further, according to an invention of claim 11, in the slide device according to any one of claims 7 to 10, left and right end portions of a first connection body 4, which is formed of a plate connected to the first member 1 or the second member 2, are bent in a U shape. A U-shaped body 11 including a groove 11a in each bent portion 12 is provided so as to form the concave guide rail portion 3 or the concave slide portion 5. The convex slide portion 5 or the convex guide rail portion 3, which is engaged with the concave guide rail portion 3 or the concave slide portion 5, is formed with left and right end portions of a second connection body 6 that is formed of a plate connected to the second member 2 or the first member 1. The frictional resistance reducing member is formed by providing the concave portion 10 on an inner surface of the groove 11a of the U-shaped body 11 where the convex slide portion 5 or the convex guide rail portion 3 comes into pressure contact and slides with the biasing force of the biasing body 7.

Furthermore, according to an invention of claim 12, in the slide device according to claim 10 or 11, the U-shaped body 11 is made of a synthetic resin.

Moreover, according to an invention of claim 13, in the slide device according to any one of claims 7 to 12, sliding portions 15, with which the other sliding surfaces come into contact and slide, are provided at both (front and rear) end positions of the sliding surface in the sliding direction, between which the concave portion 10 is disposed, at predetermined positions of one sliding surface including the concave portion 10.

Further, according to an invention of claim 14, in the slide device according to any one of claims 7 to 13, a plurality of concave portions 10 is arranged at predetermined intervals on at least one sliding surface of the sliding surfaces of the guide rail portion 3 and the slide portion 5.

Furthermore, according to an invention of claim 15, there is provided an electronic device using the slide device according to any one of claims 7 to 14. The electronic device includes a slide device. The slide device connects a main body including an operation portion 13 with an overlapping part including a display 14, and the main body and the overlapping part are disposed to overlap with each other so that the operation portion 13 is covered during the non-operation of the operation portion 13. The overlapping part is slid substantially parallel with and relative to an overlapping surface, from a state where the main body and the overlapping part overlap with each other, thereby the operation portion 13 can be exposed. The main body is formed of the first member 1 or the second member 2 and the overlapping part is formed of the second member 2 or the first member 1 in the slide device.

Since the second invention has the above-mentioned structure, frictional resistance between the sliding surfaces of the guide rail portion and the slide portion is reduced as much as possible. Accordingly, good slide is achieved in the relative movement between the first member and the second member. In addition, there is obtained an epochal slide device providing operation and effects that have not been obtained in the past, such as excellent mass-productivity at a low cost, due to the simple structure that achieves the good slide by the shape of the sliding surface.

Further, in the inventions of claims 8 to 14, there is obtained an epochal slide device providing operation and effects that have not been obtained in the past, such as reliably obtaining good slide from the more specific structure.

Furthermore, in the invention of claim 15, it may be possible to provide an electronic device using an epochal slide device that is excellent in practicality and may reliably provide the above-mentioned operation and effects.

### BRIEF DESCRIPTION OF THE DRAWINGS

FIG. 1 is an explanatory perspective view showing a state where a first embodiment of a first invention is used;

FIG. 2 is an explanatory perspective view of a closed state of main parts that shows a slide opening/closing operation when the first embodiment of the first invention is in the use state;

FIG. 3 is an explanatory perspective view of a slide opened state of main parts that shows a slide opening/closing operation when the first embodiment of the first invention is in the use state;

FIG. 4 is an exploded explanatory perspective view of the first embodiment of the first invention;

FIG. 5 is an explanatory perspective view of base parts of the slide guide portions 1 that shows protrusions 5 formed on a base part 4B of slide guide portions 1 of the first embodiment of the first invention;

FIG. 6 is an explanatory side view of a base part 4B of the slide guide portion 1 that shows a crushing operation of the protrusions 5 of the first embodiment of the first invention;

FIG. 7 is an enlarged explanatory side cross-sectional view of main parts when the first embodiment of the first invention is in the use state;

FIG. 8 is an explanatory perspective view showing that a second embodiment of the first invention is in the use state;

FIG. 9 is an explanatory perspective view of a closed state of main parts that shows a slide opening/closing operation when the second embodiment of the first invention is in the use state;

FIG. 10 is an explanatory perspective view of a slide opened state of main parts that shows a slide opening/closing operation when the second embodiment of the first invention is in the use state;

FIG. 11 is an exploded explanatory perspective view of the second embodiment of the first invention;

FIG. 12 is an explanatory perspective view of a slide surface forming member 4A that shows protrusions 5 are formed on the slide surface forming member 4A of the second embodiment of the first invention;

FIG. 13 is an enlarged explanatory cross-sectional view of main parts when the second embodiment of the first invention is in the use state;

FIG. 14 is an explanatory view showing that a first embodiment of a second invention is in the use state;

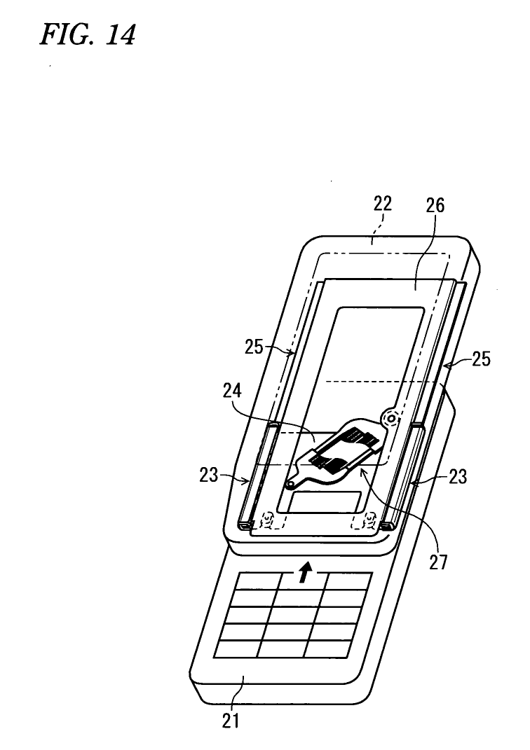

FIG. 15 is an exploded perspective view showing the first embodiment of the second invention;

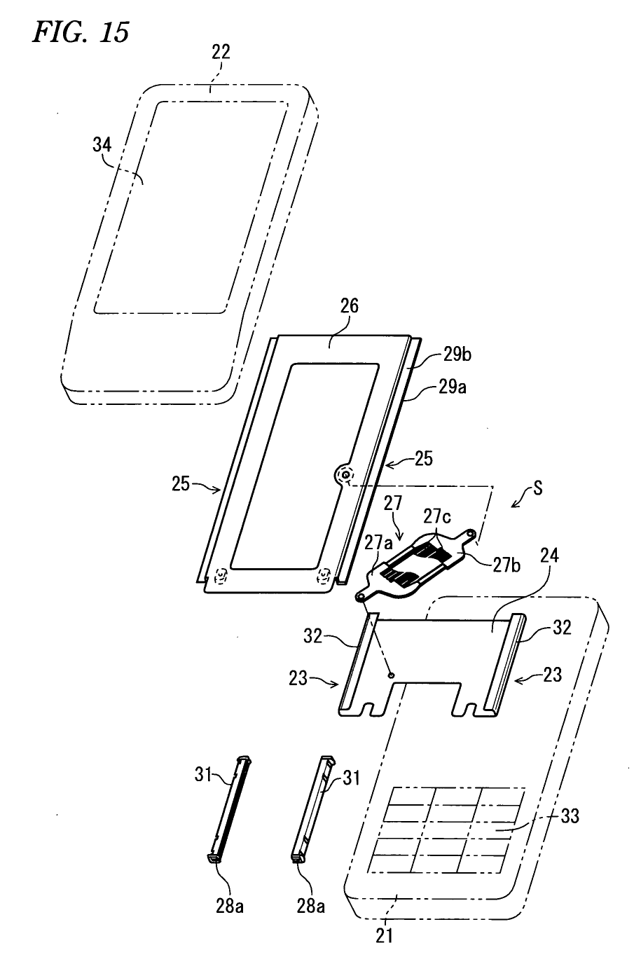

FIG. 16 is an explanatory cross-sectional view of main parts according to the first embodiment of the second invention;

FIG. 17 is a cross-sectional view taken along a line X-X of FIG. 16;

FIG. 18 is a cross-sectional view taken along a line Y-Y of FIG. 16;

FIG. 19 is an explanatory view illustrating the schematic operation of the first embodiment of the second invention;

FIG. 20 is an explanatory view illustrating the schematic operation of the first embodiment of the second invention;

FIG. 21 is an explanatory cross-sectional view of another type of main parts according to the first embodiment of the second invention;

FIG. 22 is a perspective view of main parts according to a second embodiment of the second invention;

FIG. 23 is a front view of main parts according to the second embodiment of the second invention;

FIG. 24 is an explanatory cross-sectional view of main parts according to the second embodiment of the second invention;

FIG. 25 is a cross-sectional view taken along a line Z-Z of FIG. 24, and

FIG. 26 is an explanatory cross-sectional view of main parts in the related art.

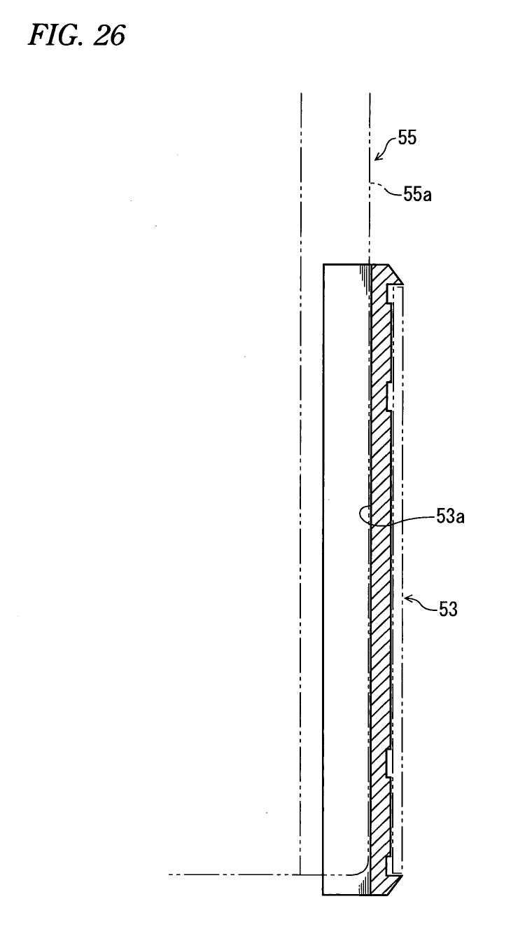

### BEST MODE FOR CARRYING OUT THE INVENTION

A first invention and the operation thereof will be briefly described with reference to drawings.

In this embodiment, protrusions 5 are provided so as to have a height so that a slide part 2 may not be slidably engaged between slide guide portions 1 due to the protrusions 5.

For example, protrusions 5 having a predetermined height are formed on slide surfaces 3 (where slide guide portions 1 or a slide part 2 are engaged) of a slide part 2 or slide guide portions 1, or the positions of the slide surfaces 3 are positioned inward and protrusions 5 having a predetermined height t are formed at portions except for the slide surfaces 3 where a distance between the slide surfaces 3 is slightly decreased. For example, by half-blanking such as pressing, protrusions 5 are formed on slide surfaces 3 of the slide part 2 or left and right slide guide portions 1 or both end portions of a portion, which determines the positions of the slide surfaces 3, in a slide direction.

Since the protrusions 5 obstruct or a distance between the slide surfaces 3 is decreased due to the protrusions 5, the slide part 2 may not be slidably engaged. That is, for example, the protrusions 5 obstruct, so that the slide part 2 may not be inserted between the slide guide portions 1 at first.

For this reason, by using a jig for pressing the protrusions so that the protrusions 5 have a predetermined height with respect to a reference surface, for example, a manual press device such as a hand press, a device, which may adjust a press position with respect to a reference surface, such as an automatic pressing machine, or a device that may adjust a crushed amount, an upper portion of each of the protrusions 5 is crushed so that the height of each protrusion is reduced.

Further, if the slide part 2 is still not slidably engaged between the slide guide portions 1, the protrusions 5 are further crushed so that the height of each protrusion is reduced.

Furthermore, if the slide part 2 may be slidably engaged between the slide guide portions 1 at last, the slide part 2 may be slidably engaged almost without clearance. That is, the slide part may be slidably engaged while clearance is close to zero as much as possible.

The appropriate height of the protrusion, which changes a state where the slide part may not be slidably engaged between the slide guide portions (the height of the protrusion where the slide part may not be slidably engaged between the slide guide portions) in an initial state of the slidable engagement between the slide guide portions 1 and the slide part 2 as described above into a state where the slide part may be slidably engaged between the slide guide portions (the height of the protrusion where the slide part may be slidably engaged between the slide guide portions), is found while the protrusion 5 is crushed.

The slide part may be slidably engaged by crushing the protrusions one time. Alternatively, the height of the protrusion or a crushed amount for allowing the slidable engagement may be determined while the protrusions are gradually crushed a plurality of times. Even though the crushed amount is determined by crushing the protrusions one time, it may be possible to sufficiently suppress clearance as compared with when these protrusions are not crushed. Further, it may be possible to provide an effect to achieve the slidable engagement, with less looseness.

It is preferable that the final crushed amount or height of the protrusion be probed so that the protrusion has the height for allowing the slide part to be slidably engaged through a plurality of times of gradual crush of the protrusion (for example, the height of the protrusion for allowing the slide part to be slidable by the gradual change of the height of the protrusion with respect to a press reference surface of a crush jig). However, if the protrusion is crushed a plurality of times, manufacturing efficiency may significantly deteriorate. For this reason, it is preferable that the height of the protrusion be set to allow the slide part to be slidably engaged by performing the crushing operation in a range of 1 to 2 or 3 to 4 times (specifically, by gradually increasing the crushed amount at several steps or by gradually lowering down the position of the press).

If the crushed amount of the protrusion 5 is set (determination of the height of the protrusion) for a sample of each of the part, such as the slide guide portions 1, the slide part 2, or components 4 forming these in this way, it may be possible to mass-produce a slide device that has small clearance and does not have looseness even though the crushing operation of the protrusion is not performed at the time of the slidable assembly of the respective parts if the accuracy of the product is high, the variation of the dimension accuracy of each part is small, and the protrusions are automatically and uniformly crushed so that the height of the protrusion becomes the predetermined height of the protrusion.

That is, for this reason, it may be possible to achieve the slidable engagement where clearance is close to zero as much as possible, and to achieve a slide device that has no looseness even though being mass-produced.

Further, when a slide part is slidably engaged with still another type (another lot) parts, looseness is increased due to the difference in dimensions or the slide part may not be slidably engaged. In this case, appropriate height of each protrusion is determined by crushing each protrusion again as described above (a crushed amount is set by performing a crushing operation again).

The protrusions 5 may be formed on the slide surfaces 3 between the slide part 2 and the slide guide portions 1. Even though being not directly formed on the slide surfaces 3, the protrusions may be formed on surfaces that are portions except for the slide surfaces 3 and eventually determine the positions of the slide surfaces 3 by coming into contact with other parts. For example, the protrusions may be formed on the slide surfaces 3 of the slide part 2 or the slide guide portions 1. The slide guide portions 1 or the slide part 2 are formed by components 4 forming these, that is, for example, a base part 4B and slide surface forming members 4A, or spacer members further interposed therebetween, and the protrusions may be formed on the slide surfaces 3 of the slide surface forming members 4A. However, like in a second embodiment to be described below, protrusions 5 may be formed so as to come into contact with the receiving surfaces of the base part 4B that are the back sides opposite to the slide surfaces 3 of the slide surface forming members 4A. The protrusions 5 are not formed on the slide surface forming members 4A, and may be formed on the receiving surface of the base part 4B so as to come into contact with the slide surface forming members 4A. The positions of the slide surfaces 3 may be eventually determined by the height of the protrusions 5.

That is, the protrusions 5 may be directly formed on the slide surfaces 3. However, the protrusions 5 may be formed so that a distance between the slide surfaces 3 of left and right slide guide portions 1 or a distance between both slide surfaces 3 of the slide part 2 is finely adjusted by the protrusions 5.

Further, for the slidable engagement between the slide guide portions 1 and the slide part 2, one of the slide guide portion and the slide part may be formed in a concave shape and the other thereof may be formed in a convex shape. Furthermore, the protrusions may be formed on both left and right slidable engagement portions 2A of the slide part 2 and the left and right slide guide portions 1, or may be formed only on one thereof.

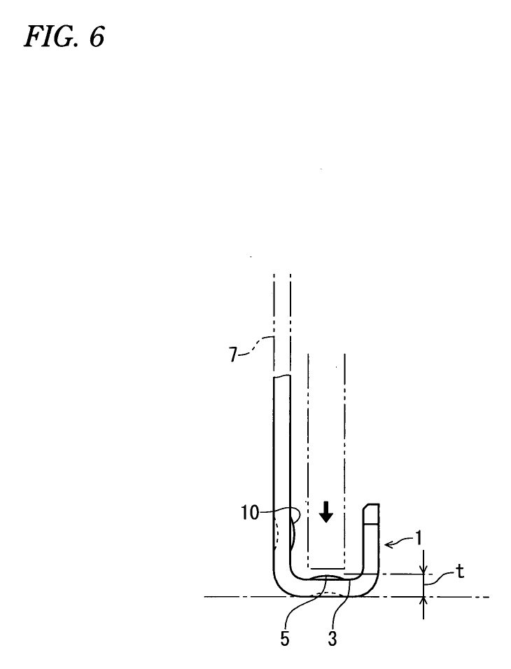

Moreover, the protrusions 5 may have a dot shape or a linear shape. One protrusion may be formed or a plurality of protrusions may be formed. However, if the protrusions are formed on both end portions of a slide range of the slide part 2 with respect to the slide guide portions 1, looseness is further reduced. Further, in order to allow the slide part to smoothly slide, it is preferable that the protrusion have a rounded and protruding shape such as a hemispherical protrusion and an apex of the protrusion be crushed so that a protruding edge of the protrusion becomes further round to make the slide part slide well. Furthermore, the protrusion 5 is formed to have a protruding height t (see FIG. 6), which gradually increases or decreases in the slide direction, in consideration of a correspondence relationship with the slide part 2. Alternatively, protrusions having appropriate height and size may be formed as occasion demands.

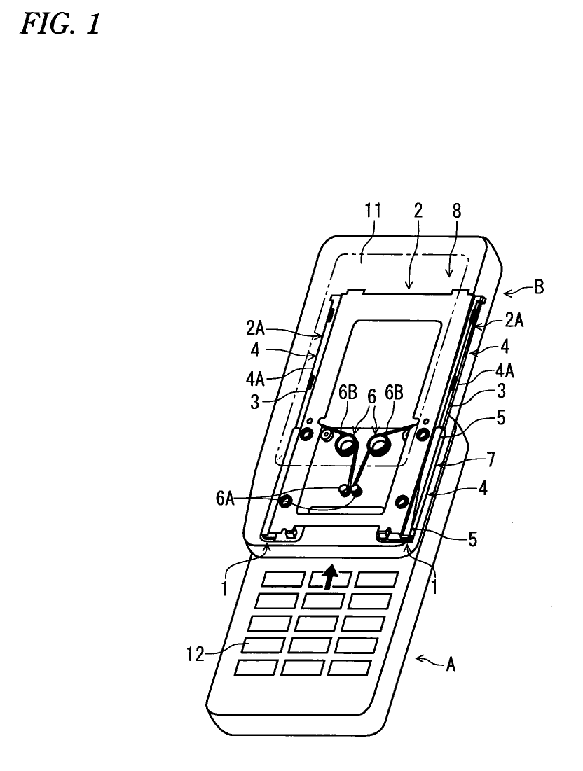

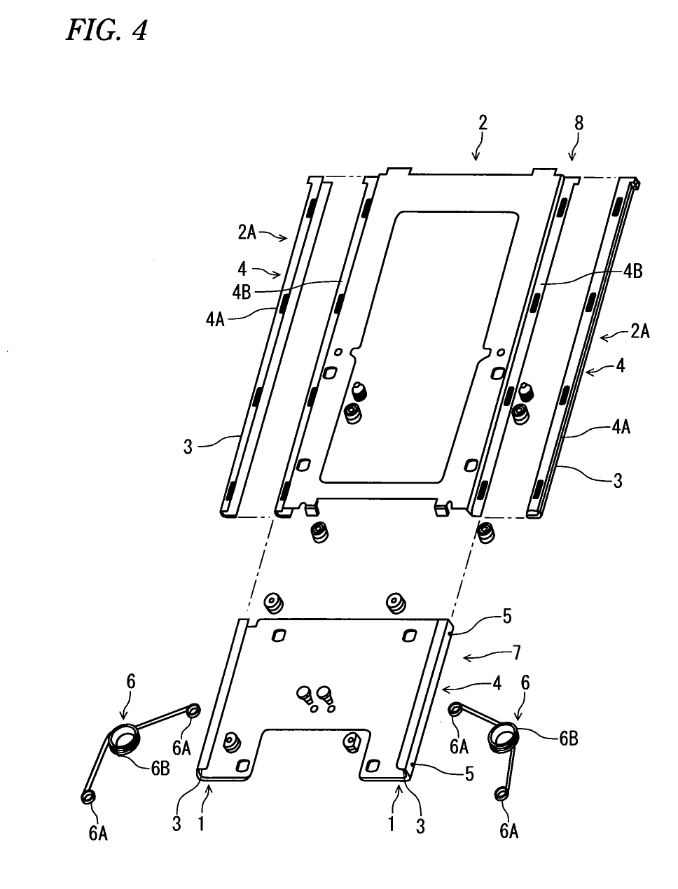

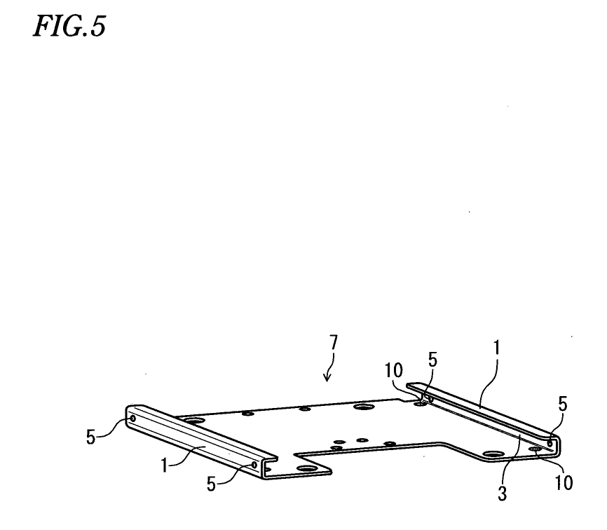

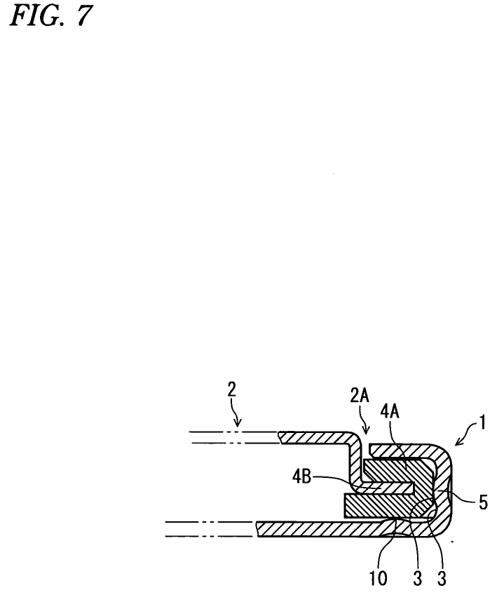

A specific first embodiment of the first invention will be described with reference to drawings (FIGS. 1 to 7).

This embodiment is obtained by applying the invention to a mobile phone, and relates to the following slide device. A main body, which includes an operation portion 12 where numeric keys and function keys are arranged on an upper surface thereof, is referred to as a first member A. An overlapping part, which slidably overlaps with the first member and opens and closes the operation portion 12 so as to cover or expose the operation portion from or to the outside, is referred to as a second member B. A display 11 such as a liquid crystal panel, which makes a predetermined display, is provided on an upper surface of the second member B, and the first and second members A and B are slidably connected to each other by a slide device.

That is, in this embodiment, the slide part 2 provided at the second member B used as the overlapping part is slidably engaged between the slide guide portions 1 that are provided at the first member A used as the main body. The slide device connects the first member with the second member so that the second member B is slidable relative to the first member A.

Specifically, the slide guide portions 1 have been formed in the shape of a guide rail so as to face each other on the left and right sides of the upper surface of the first member A. However, in this embodiment, the slide guide portions 1 are formed at left and right edges of a slide guide portion forming plate by folding left and right edges of the slide guide portion forming plate.

Meanwhile, the slide part 2, which is slidably engaged between the slide guide portions 1, is provided on an overlapping surface of the second member B.

The slide part 2 is formed so that plate edges as the slidable engagement portions 2A, which are slidably engaged with the respective slide guide portions 1, protrude from the both (left and right) edges of a slide part forming plate. The plate-like slide part 2, which includes the slidable engagement portions 2A on the left and right sides thereof as described above, is slidably engaged between the left and right slide guide portions 1.

Specifically, in this embodiment, the slide surface forming members 4A made of a synthetic resin are fitted to the left and right plate edges of the base part and the slide surface forming members 4A made of resin are slidably engaged with the respective slide guide portions 1 as the slidable engagement portions 2A so that the slide part slides well.

In the first invention, the protrusions 5 may be directly formed on the slide guide portions 1 or the slide surfaces 3 of the slide part 2, that is, the slide surfaces 3. Alternatively, the protrusions may be formed on portions that exclude the slide surfaces 3 and eventually determine the positions of the slide surfaces 3. That is, for example, the slide guide portions 1 or the slide part 2 are formed by assembling a plurality of components 4 and the protrusions 5 may be formed between the respective components 4. That is, the slide guide portions 1 or the slide part 2 are formed of a plurality of components 4, such as the base part 4B and the slide surface forming member 4A, and spacer members, which are interposed therebetween, in some cases, and the protrusions 5 may be directly formed on the slide surfaces 3 of the components 4 (the slide surfaces 3 of the slide surface forming members 4A). Alternatively, the protrusions 5 may be formed on the back sides opposite to the slide surfaces 3 of the slide surface forming members 4A so as to come into contact with the base part 4B or the spacer members. Alternatively, the protrusions 5 may be formed on the base part 4B so as to come into contact with the spacer members or the slide surface forming members 4A. In any case, at first, there are provided the protrusions 5, which have a height where the slide part 2 may not be slidably engaged between the slide guide portions 1, or the protrusions 5 that eventually make a distance between the slide surfaces 3 small not to allow the slide part to be slidably engaged.

In this embodiment, the protrusions 5 are directly formed on the slide surfaces 3 of the slide guide portions 1. U-shaped portions, which are formed of a metal plate in the shape of a guide rail by folding the end portions of the plate as described above, are formed as the slide guide portions 1 as they are. Further, the protrusions 5, which protrude in the left-and-right direction, are formed on the slide surfaces of the U-shaped bottoms of the U-shaped portions. The protrusions 5, which protrude from the bottom of the folded metal plate, are crushed so as to have a predetermined height t, so that the slide part 2 may be slidably engaged between the slide guide portions 1.

The protrusions 5 are formed on at least both end portions of the slide range of the slide part 2 with respect to the slide guide portions 1. That is, the protrusions 5 may be formed at one or more positions. However, if the protrusions are formed on both end portions of the slide range, it may be possible to stably engage the slide part between the slide guide portions without looseness, to always make the slide part smoothly slide, and to suppress looseness as much as possible.

Further, it is preferable that the protrusions 5 protrude in a rounded and protruding shape. If the protrusions are formed as described above, the edge of the protrusion becomes round even though the protrusion is crushed or the apex of the protrusion is crushed in a flat shape. Accordingly, the slide part smoothly slides.

For this reason, it is preferable that the protrusion protrude in a hemispherical shape. However, the protrusion may be formed so as to have a length.

In this embodiment, U-shaped rail portions are formed as the slide guide portions 1, as they are, by folding the plate edges of a slide guide forming plate that forms the slide guide portions 1. The hemispherical protrusions 5, which are protruded inward from the outside in the left-and-right direction by a press, are formed in total at four positions of both end portions of the inner surfaces of the slide guide portions 1 in the slide direction and in the left-and-right direction. Since the protrusions are formed at the bottom of the metal plate, which is folded in a U shape, by a press, it is very easy to form the protrusions and also to perform a crushing operation. As a result, the slide part may stably and smoothly slide.

Further, the protrusions 5 may be formed at one or more positions as described above and one protrusion may be formed so as to be elongated in the slide direction over from end to end. Even in this case, it is preferable that the protrusions protrude in a rounded and protruding shape. Furthermore, the protrusions may be disposed in the order of size, may be appropriately scattered, or the height of the protrusion may increase or decrease in the slide direction over from end to end.

Moreover, the pair of slide guide portions 1 formed at the first member A in this embodiment, that is, the slide guide portion forming plate, which includes the slide guide portions 1 formed at the left and right sides thereof, is provided at the first member A as a first connection body 7 in this embodiment. The plate-like slide part 2, which includes the slidable engagement portions 2A (to be engaged with the slide guide portions 1) formed at the left and right sides thereof, is provided at the second member B as a second connection body 8. The first and second connection bodies 7 and 8 are connected to each other by elastic members 6 so that biasing force for making the second connection body “return” in a direction opposite to the slide direction is generated until the second connection body 8 slides relative to the first connection body 7 for a predetermined distance, by contrast, biasing force for making the second connection body “move forward” in the slide direction is generated if the second connection body slides for a predetermined distance.

Specifically, one end of each elastic member 6 is connected to the first connection body 7, and the other end thereof is connected to the second connection body 8.

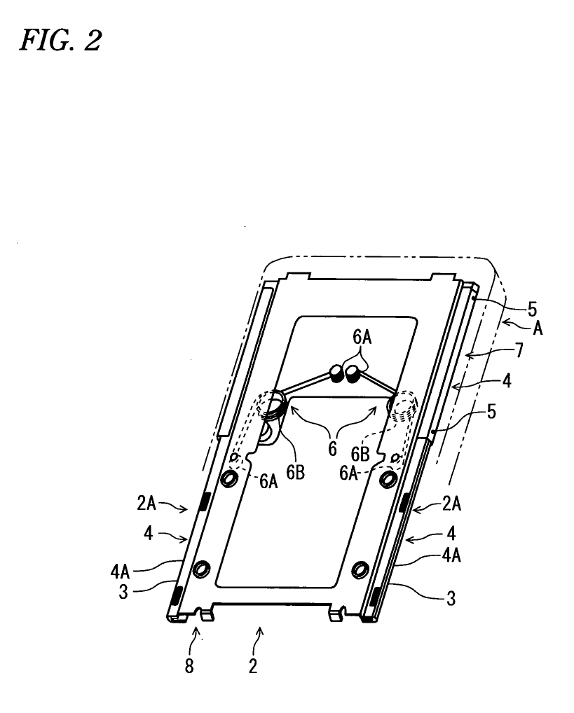

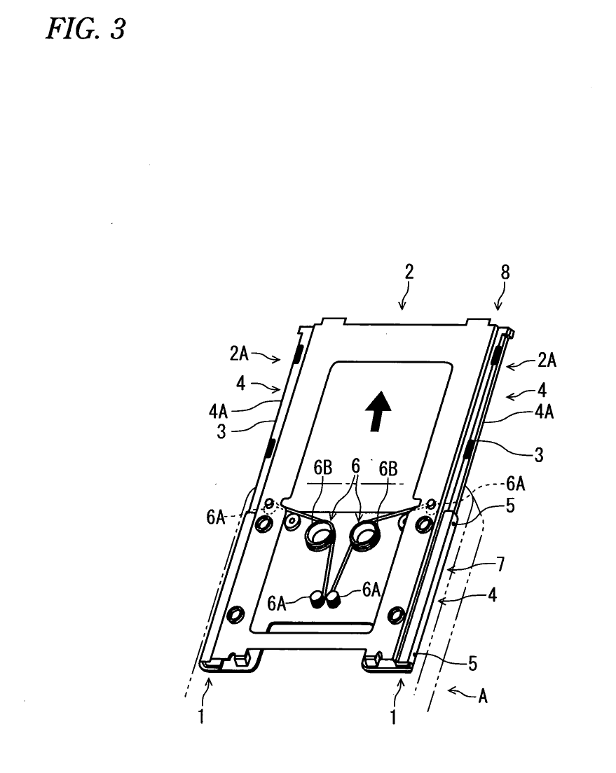

A coil spring 6, which includes connection ends 6A formed at right and left ends and a coil-shaped portion 6B formed at an apex by winding the middle portion of the coil spring and is formed in a “V” shape as a whole as shown in FIGS. 2 and 3, is employed as the elastic member 6. Accordingly, angle increasing biasing force is generated so as to separate the connection ends 6A, which are formed at the right and left ends of the coil spring 6, from each other.

Further, the one connection end 6A of the elastic member 6 is connected to the first connection body 7, and the other connection end 6A is connected to the first connection body 7.

Meanwhile, for example, a V-shaped leaf spring or a V-shaped wire spring may be employed other than the coil spring 6 having the above-mentioned structure, and return biasing force or forward biasing force is generated by a cam face and a roller that is biased against the cam face by a spring.

Accordingly, when the first and second members A and B overlap with each other, the first and second members are pushed so as to return (be closed) in a direction where the first and second members A and B overlap with each other by the biasing force for stretching the elastic member 6.

If the second member B slides from this state so as to be protruded from the first member A for a predetermined length against the biasing force of the elastic members 6, the connection ends 6A of the elastic members 6 are arranged in the lateral directions of the first and second member A and B. The connection ends 6A of the elastic members 6 in this state are biased in the substantially lateral direction so that an angle between the connection ends is increased. Accordingly, the closing biasing force in an overlap closing direction is hardly generated. If the second member B slides so as to be further protruded from the first member A than this position, the other connection end 6A connected to the second member B further slides toward the slidably protruding side of the second member B than one connection end 6A, so that a balance of the elastic member 6 is lost and the elastic member 6 is widened. Therefore, in this case, biasing force (opening biasing force) is generated in a direction where the second member B protrudes from the first member A.

That is, until the first and second members A and B pass a predetermined position, closing biasing force is generated in the overlap closing direction. Meanwhile, if the first and second members A and B have passed a predetermined position and slide to be opened, opening biasing force is generated in the direction where the second member B slides to protrude from the first member A.

Further, in this embodiment, the protrusions 5 have been crushed so as to have an appropriate height, so that clearance in the left-and-right direction is made to be close to zero and looseness in the left-and-right direction is suppressed. However, protrusions 10 are formed even on the upper and lower portions of the parts of the slide portion, and the looseness in the up-and-down direction is further adjusted by crushing the protrusions likewise or by changing the degree of flexion of upper and lower portions that form pressing portions of the parts. Accordingly, clearance is suppressed.

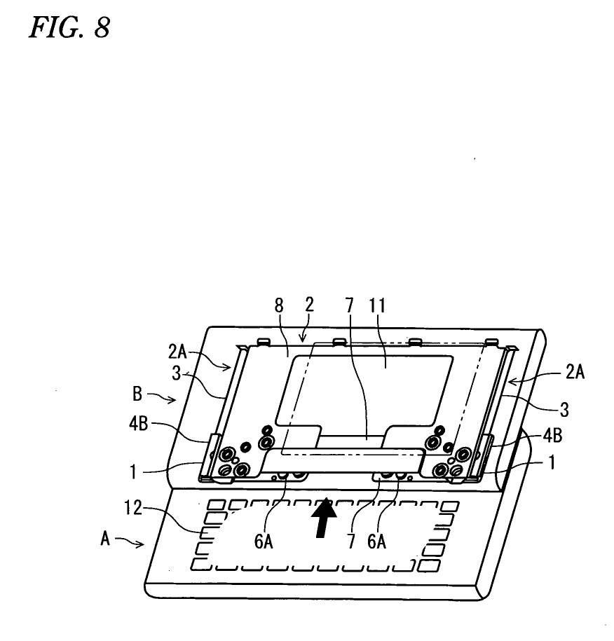

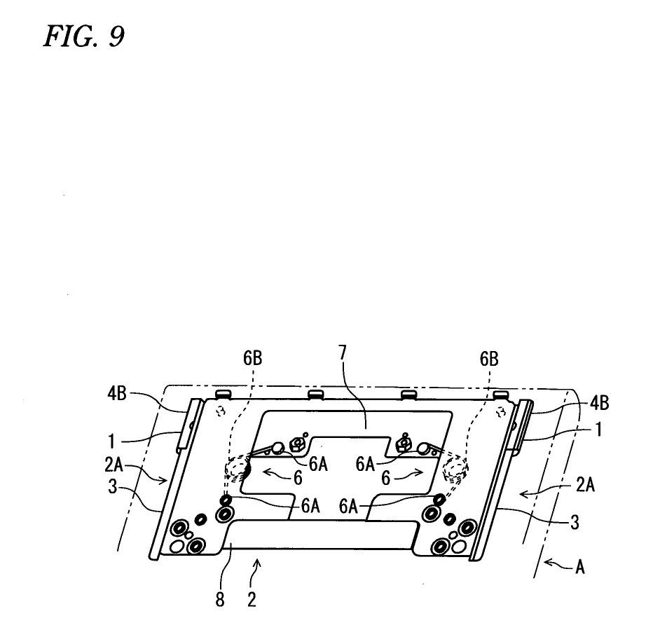

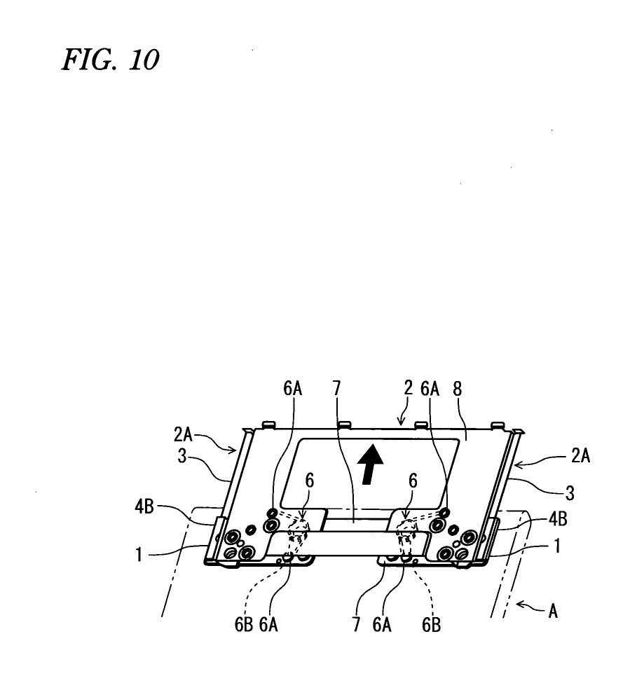

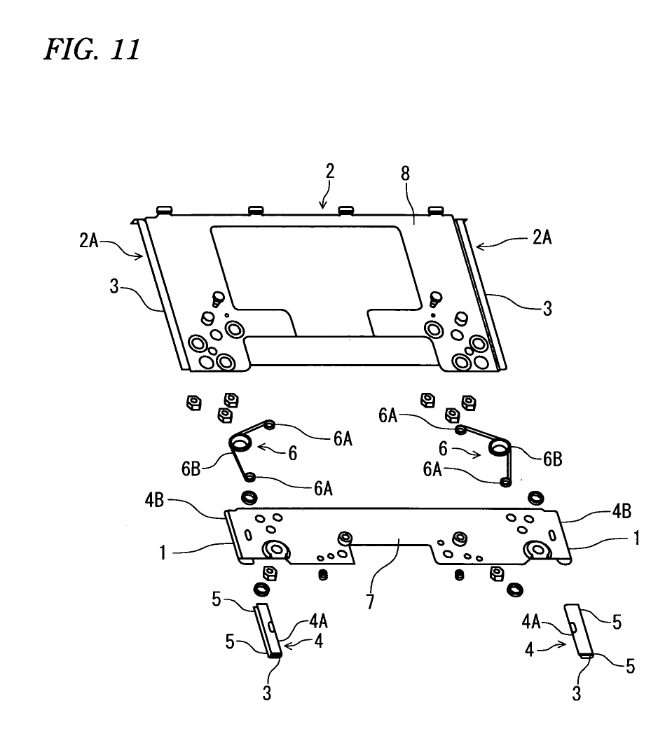

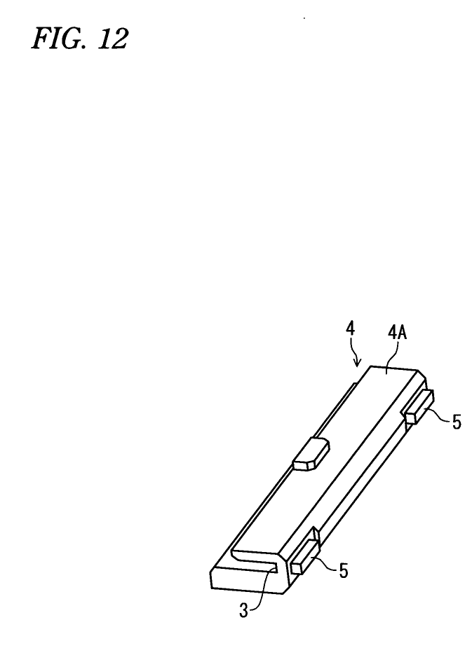

This embodiment (FIGS. 8 to 13) is obtained by applying the invention to a portable personal computer. Unlike in the first embodiment, protrusions 5 are not formed on slide surfaces 3 of a slide part 2 or the slide guide portions 1 but the protrusions 5 are formed on components 4 that form slide guide portions 1.

That is, in this embodiment, a base part 4B, which forms the slide guide portions 1 made of a folded metal plate, is not used as the slide guide portions 1 as it is. This is used as the base part 4B (component 4) forming the slide guide portions 1 like the slidable engagement portions 2A of the slide part 2 of the first embodiment, and the slide guide portions 1 are formed by engaging and assembling slide surface forming members 4A, which are made of a resin, with the base part 4B. Accordingly, the smooth sliding movement is achieved. If being abraded, the slide surface forming members 4A may be replaced in some cases like the slidable engagement portions 2A of the slide part 2 of the first embodiment.

In this embodiment, the protrusions 5 are not formed on the slide surfaces 3 of the slide surface forming members 4A, and the protrusions 5 coming into contact with the inner surface of the base part 4B are formed on the back sides opposite to the slide surfaces 3 of the slide surface forming members 4A so as to protrude in the left-and-right direction.

The positions of the slide surfaces 3 of the slide surface forming members 4A are adjusted to be extended out and retracted in by the height of each protrusion 5, and the protrusions 5 are crushed so as to have a predetermined height.

Meanwhile, the first invention is not limited to the first and second embodiments, and the design of the specific structure of each component may be modified appropriately.

The protrusions 5 have been formed on the components 4 of the slide guide portions 1 in any one of the first and second embodiments. However, for example, the protrusions 5 may be formed on the components 4 of the slidable engagement portions 2A of the slide part 2.

Further, if the slide part 2 or the slide surfaces 3 of the slide guide portions 1 are formed through the pressing of a metal plate, a pressed surface is a rough surface or longitudinal stripes are formed in a direction orthogonal to the slide direction by a press, so that concavity and convexity are formed. Therefore, the smooth slide of the slide part is inhibited by the concavity and convexity. Furthermore, in this embodiment, the slide surface is formed into a smooth surface by a cutting apparatus or a polishing apparatus after pressing. According to the cutting or polishing, it may be possible to avoid the inhibition of the above-mentioned smooth slide and to obtain predetermined dimensions. Therefore, it may be possible to obtain an advantage of improving dimensional accuracy.

Preferred embodiments of a second invention will be briefly described below with reference to drawings.

Slide portions 25, which are provided at a first member 21 or a second member 22, slide along guide rail portions 23 that are provided at the first or second member 21 or 22, so that the relative movement between the first and second members 21 and 22 is performed. Further, a biasing force is applied to the relative movement between the first and second members 21 and 22 by a biasing body 27 that is disposed between the first and second members 21 and 22. One end of the biasing body is connected to the first member 21 and the other end thereof is connected to the second member 22.

Specifically, the second invention has a function to bias the first and second members 21 and 22 in a direction of separating them from one another. For example, if one end of the biasing body 27 is connected to the first member 21 and the other end of the biasing body 27 is connected to the second member 22, return biasing force for making the second member 22 return in a return direction is generated until the second member 22 slides relative to the first member 21 for a predetermined distance. Further, forward biasing force for making the second member slide forward is generated when the second member slides to move forward for a predetermined distance. Accordingly, a biasing operation for slidably biasing the second member 22 relative to the first member 21 is obtained.

Meanwhile, according to the second invention, between sliding surfaces of the guide rail portion 23 and the slide portion 25, which come into pressure contact with each other and slide with each other, with the biasing force of the biasing body 27 when the first and second members 21 and 22 move relative to each other in the slide direction due to the biasing force of the biasing body 27, a concave portion 30, which does not come into contact with the other sliding surface, is formed on at least one sliding surface. Accordingly, there is provided the frictional resistance reducing member that reduces frictional resistance between the sliding surfaces through the reduction in area. Good (smooth) slide, which has small sliding resistance between the guide rail portion 23 and the slide portion 25, is obtained from this structure. Therefore, good slide is achieved in the relative movement between the first and second members 21 and 22.

Further, according to the second invention, the frictional resistance reducing member is formed by simply forming the concave portion 30, which does not come into contact with the other sliding surface, on at least one sliding surface of the sliding surfaces of the guide rail portion 23 and the slide portion 25. Accordingly, even though a special material is not employed on the sliding surface, it may be possible to achieve good slide by setting the shape. As a result, the second invention has excellent mass-productivity at a low cost.

Furthermore, according to the second invention, grease for reducing the frictional resistance between the sliding surfaces does not need to be used. Accordingly, it may be possible to reliably solve a problem that may be generated when the above-mentioned grease is used.

A specific first embodiment of the second invention will be described with reference to drawings.

This embodiment is obtained by applying the invention to a mobile phone that becomes compact by overlap. An operation portion 33, which has the function of a keyboard where numeric keys, function keys, and the like are arranged, is provided on an upper surface of a first member 21 (main body 21), which has the shape of an elongate and thick plate, where electronic components such as a circuit substrate and a power source are built in a case. A second member 22 (overlapping part 22), which has substantially the same shape of an elongate and thick plate and overlaps with the main body 21 so as to cover the operation portion, is connected to the main body by a slide device S so as to substantially horizontally slidable in a front-and-rear direction (a direction of an overlapping surface).

A preset screen or a display 34 such as an elongate liquid crystal panel is provided on the upper surface of the overlapping part 22 during the overlapping and closing of the overlapping part. The display makes a predetermined display by the operation of the operation portion or arrival of signal and can display an image, which is elongated in a lateral direction, such as a TV or a DVD acquired from received signals.

The main body 21 and the overlapping part 22 are connected to each other by the slide device S, the overlapping part 22 may be opened and closed so as to slide relative to the main body 21, and the overlapping part slidably moves between an overlapping-closed position where the operation portion of the main body 21 is covered with the overlapping part 2 and a slidably opened position where the overlapping part 22 slides in the front-and-rear direction and exposes the operation portion to the outside so that the position of the overlapping part 22 is deviated.

The slide device S of this embodiment will be described first.

The slide device S connects the first member 21 (main body 21) with the second member 22 (overlapping part 22) so that the first and second members are slidable in a length direction.

The second member is disposed to overlap with the first member (main body 21). The slide device S includes concave or convex guide rail portions 23 that are provided at the main body 21 or the overlapping part 22, concave or convex slide portions 25 that are provided at the overlapping part 22 or the main body 21 and relatively moves along the guide rail portions 23, and a biasing body 27 of which one end is connected to a first connection body 24 and the other end is connected to a second connection body 26. The biasing body biases the first and second connection bodies so that the first and second connection bodies 24 and 26 move relative to each other in the slide direction. In this embodiment, there are provided the first connection body 24 that connects the guide rail portions 23 with the main body 21, and the second connection body 26 that connects the slide portions 25 with the overlapping part 22. Meanwhile, the guide rail portions 23 or the slide portions 25 may be directly (integrally) formed at the main body 21, and the guide rail portions 23 or the slide portions 25 may be directly (integrally) formed at the overlapping part 22.

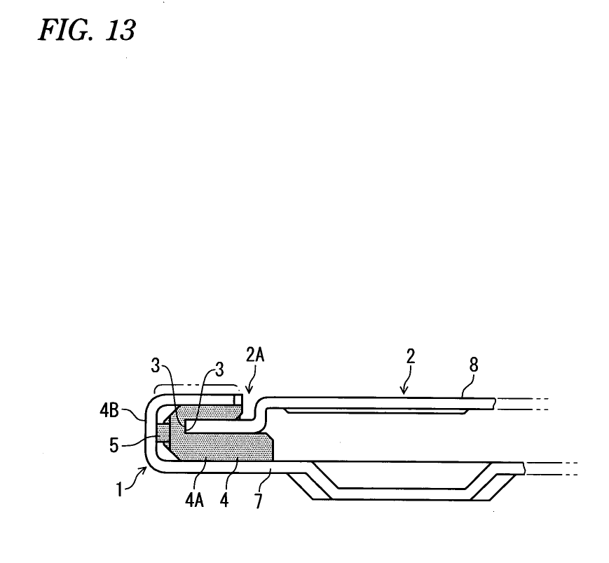

Specifically, as shown in FIG. 13, left and right end portions of the first connection body 24, which is formed of a metal plate, are bent in a U shape, and a U-shaped body 31 including a groove 31a is disposed in each U-shaped portion 32, so that concave guide rail portions 23 are formed. End portions of the second connection body 26, which is formed of a metal plate, form convex slide portions 25 that are engaged with the concave guide rail portions 23.

Accordingly, the slide portions 25 of the second connection body 26 slide along the guide rail portions 23 of the first connection body 24, so that the overlapping part 22 is slidable relative to the main body 21.

Further, according to the this embodiment, between the sliding surfaces of the guide rail portion 23 and the slide portion 25, which come into pressure contact with each other and slide with each other, with the biasing force of the biasing body 27 to be described below when the first and second connection bodies 24 and 26 move relative to each other in the slide direction due to the biasing force of the biasing body 27, a concave portion 30, which does not come into contact with the other sliding surface and has a length in the sliding direction, is formed on at least one sliding surface. Accordingly, there is provided the frictional resistance reducing member that reduces frictional resistance between the sliding surfaces through the reduction in contact area. Meanwhile, in this embodiment, the concave portion 30, which does not come into contact with the other sliding surface and has a length in the sliding direction, has been formed on at least one sliding surface of the sliding surfaces of the guide rail portion 23 and the slide portion 25. However, the concave portions 30 may be formed on both the sliding surfaces.

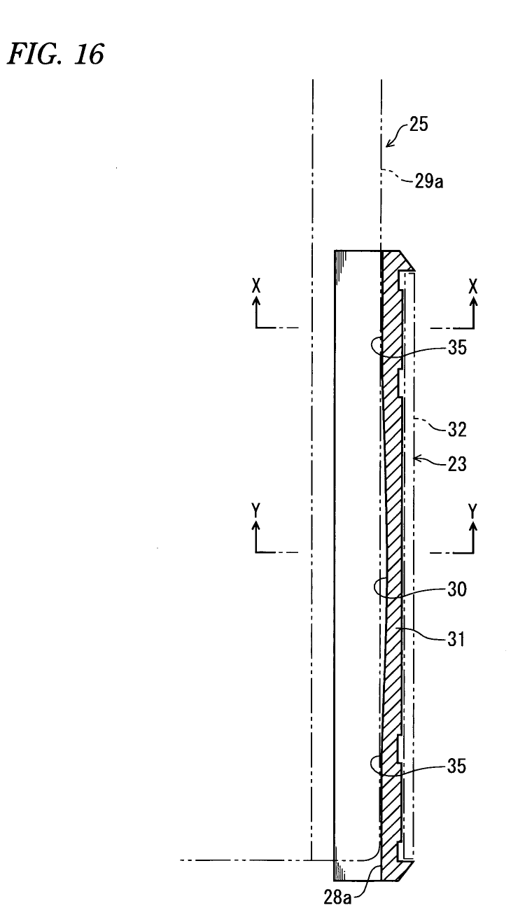

Specifically, as described above, the concave guide rail portions 23 are provided at the first connection body 24 and the convex slide portions 25, which are engaged with the guide rail portions 23, are provided at the second connection body 26. As shown in FIG. 16, the concave portion 30 is formed on a sliding surface 28a of the concave guide rail portion 23 with which a convex end sliding surface 29a positioned at the end of the convex slide portion 25 comes into pressure contact and slides with the biasing force of the biasing body 27, so that the frictional resistance reducing member is formed.

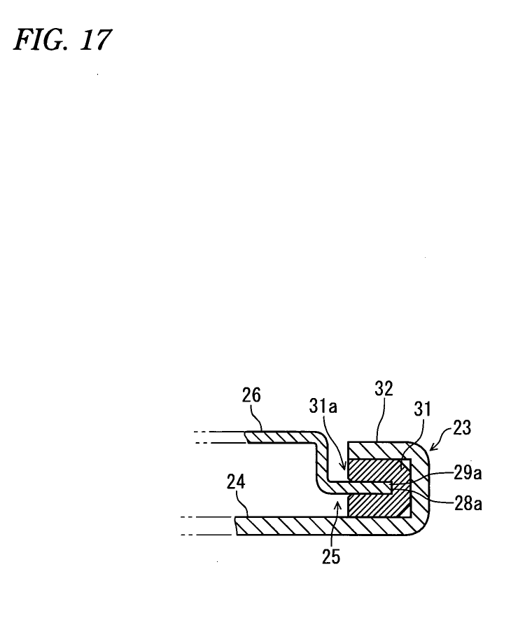

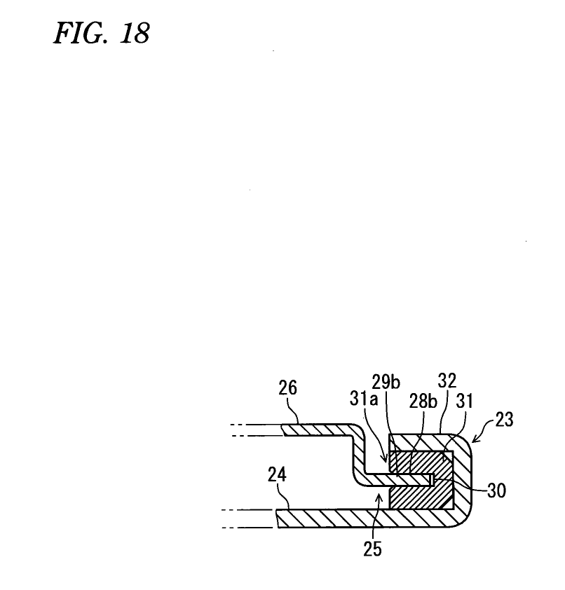

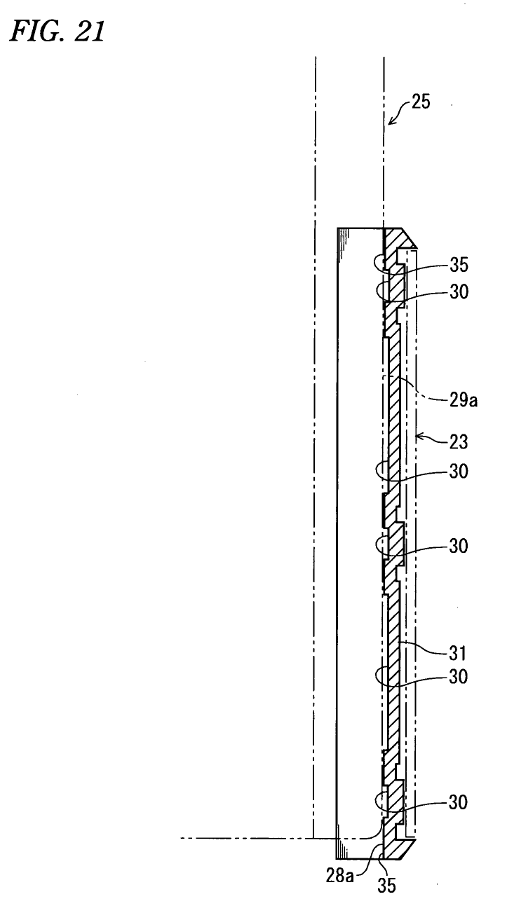

The concave portion 30 is formed by forming one curved concave portion 30 at a middle portion of the sliding surface 28a forming the guide rail portion 23 (the inner surface of the groove 31a of the above-mentioned U-shaped body 31) as shown in FIGS. 16, 17, and 18 or by arranging a plurality of concave portions 30, which have different lengths, at predetermined intervals in the length direction of the sliding surface 28a as shown in FIG. 21.

The U-shaped body 31 is one member that is formed by integrally forming members made of an appropriate synthetic resin, and is fitted into each of the bent portions 32 that are bent and formed at the both (left and right) end portions of the above-mentioned first connection body 24.

Sliding portions 35, with which the sliding surfaces 29a of the slide portions 25 come into contact and slide, are provided at both (front and rear) end positions of the sliding surface in the sliding direction, between which the concave portion 30 is disposed, at a predetermined position of one sliding surface 28a including the concave portion 30 on the inner surface of the groove 31a of the U-shaped body 31.

The reason why the sliding portions 35 are provided at both end positions of the sliding surface where the concave portion 30 is disposed at the middle thereof is to achieve the stable slide by obtaining the stroke of the sliding portion as large as possible when the concave portion 30 is formed on a slide structure (sliding portion) that is subject to the limitation of size (length).

Meanwhile, in this embodiment, a slide device S, which allows the slide portions 25 to be slidable relative to the linear guide rail portions 23, has been employed as the slide device S provided with the above-mentioned frictional resistance reducing member. However, a slide device S, which allows the slide portions 25 to be rotatable with respect to the curved guide rail portions 23, may be employed. In this case, the overlapping surface of the overlapping part 22 is substantially horizontally rotatable with respect to the main body 21. Rotating biasing force for making the overlapping part 22 return with respect to the main body 21 may be generated until the overlapping part 22 is rotated with respect to the main body 21 by a predetermined angle with the baising force of the biasing body 27. Further, forward rotating biasing force for making the overlapping part rotate forward may be generated when the overlapping part is rotated by a predetermined angle. In this case, good rotating slide is performed by the frictional resistance reducing member.

The baising body 27 used in this embodiment includes a first element 27a that is connected to the main body 21, a second element 27b that is movable with respect to the first element 27a in a separation direction and is connected to the overlapping part 22, and coil springs 27c that slidably connect the first and second elements as the first and second elements 27a and 27b are biased against each other in the separation direction (opposite direction).

Specifically, the biasing body includes a first element 27a rotatably connected to the main body 21 (first connection body 24), and a second element 27b rotatably connected to the overlapping part 22 (second connection body 26). An extendable movable body is formed by slidably connecting the first and second elements 27a and 27b in the separation direction. Coil springs 27c, which slidably bias the first and second elements 27a and 27b in the separation direction, are provided between the first and second elements 27a and 27b. Accordingly, a biasing mechanism for biasing the first and second elements 27a and 27b in the separation direction is provided at the movable body.

Accordingly, when the movable body, which is formed of the first and second elements 27a and 27b, contracts so that a pivotal connection part of the first element 27a approaches a pivotal connection part 27b of the second element, anti-contraction biasing force is generated by the coil springs 27c. The anti-contraction biasing becomes biasing forces for biasing the respective first and second connection bodies 24 and 26 in the separation direction.

When the biasing body 27 having the above-mentioned structure is provided at the slide device S connecting the main body 21 with the overlapping part 22, the pivotal connection part of the first element 27a is rotatably and pivotally connected to the main body 21 (first connection body 24) and the pivotal connection part of the second element 27b is rotatably and pivotally connected to the overlapping part 22 (second connection body 26).

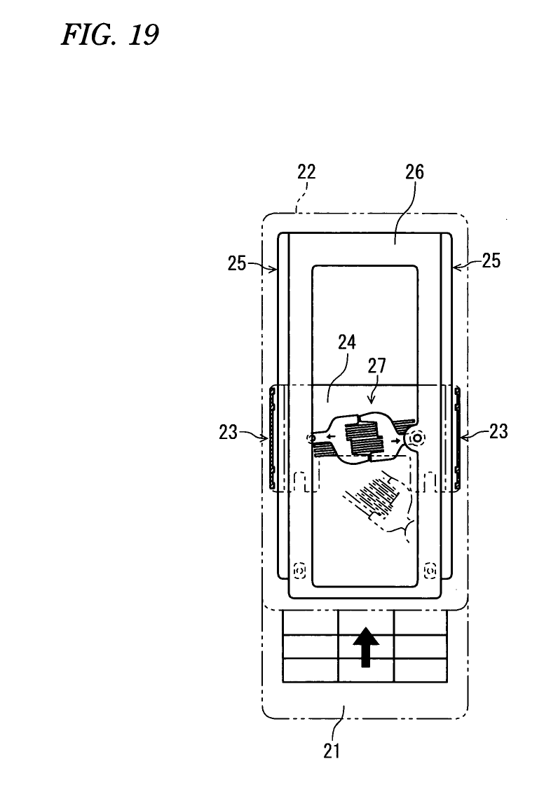

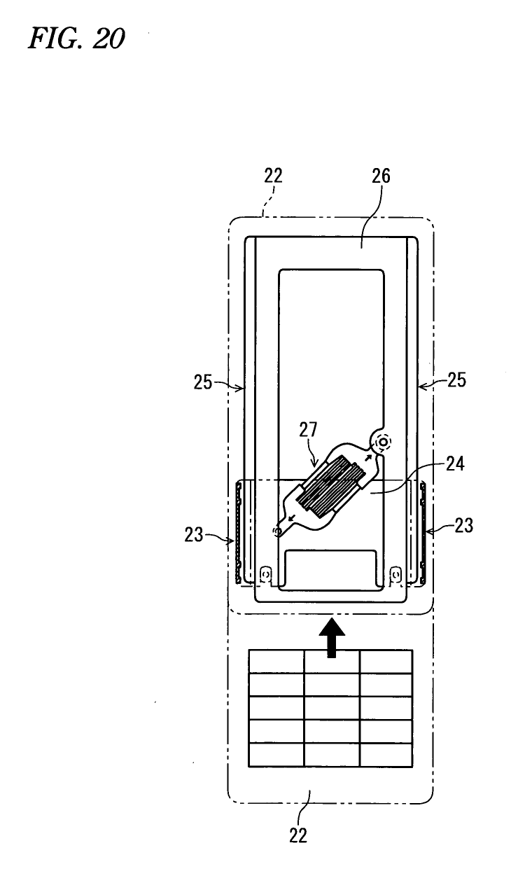

In this state, return biasing force for making the overlapping part 22 automatically and slidably return to the overlapping-closed position is generated until the overlapping part 22 slides relative to the main body 21 for a predetermined distance, by contrast, forward biasing force for making the overlapping part automatically slide forward to the slidably opened position is generated if the overlapping part is slid for a predetermined distance (see FIGS. 19 and 20).

Meanwhile, a biasing body, which is formed of a substantially V-shaped body having connection ends at left and right sides thereof and generates angle increasing biasing force for making the left and right ends of the elastic member be separated from each other, specifically, a biasing body, which is formed of a V-shaped leaf spring, a V-shaped wire spring, or a coil spring including a coil-shaped portion formed at an apex by winding the middle portion of the coil spring and formed substantially in a “V” shape as a whole, may be employed as the biasing body. If the characteristics of this embodiment are represented, any one may be appropriately employed as the biasing body.

Since this embodiment has the above-mentioned structure, frictional resistance between the sliding surfaces of the guide rail portion 23 and the slide portion 25 is reduced as much as possible as compared with the above-mentioned related art. Accordingly, good slide is achieved in the relative movement between the main body 21 (first connection body 24) and the overlapping part 22 (second connection body 26). In addition, this embodiment has excellent mass-productivity at a low cost due to the simple structure that achieves the good slide by the shape of the sliding surface.

Further, according to this embodiment, grease for reducing the frictional resistance between the sliding surfaces does not need to be used. Accordingly, it may be possible to reliably solve a problem that may be generated when grease is used.

A specific second embodiment of the second invention will be described below with reference to drawings.

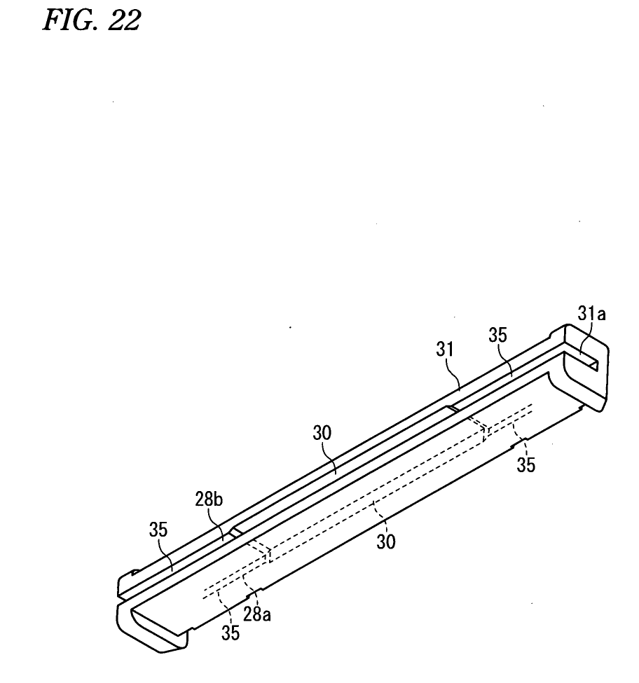

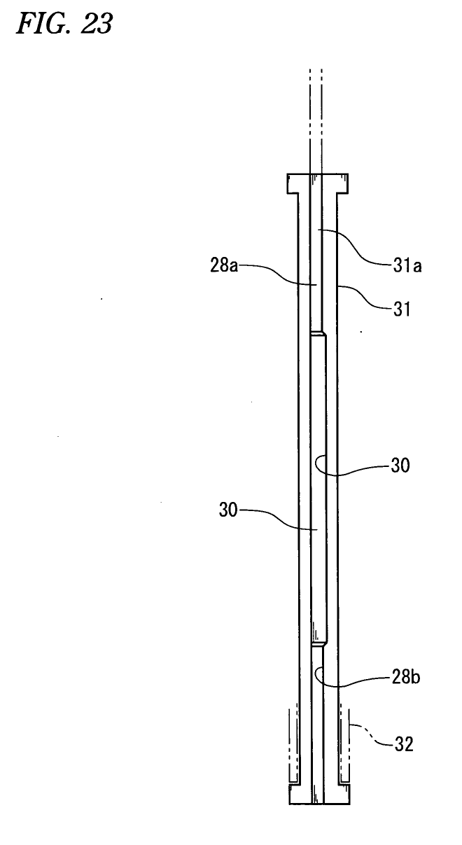

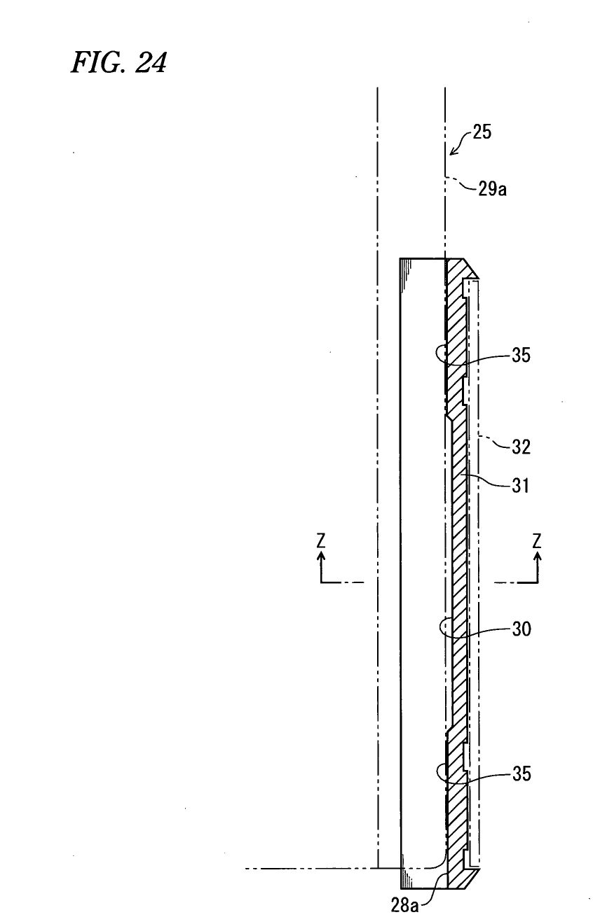

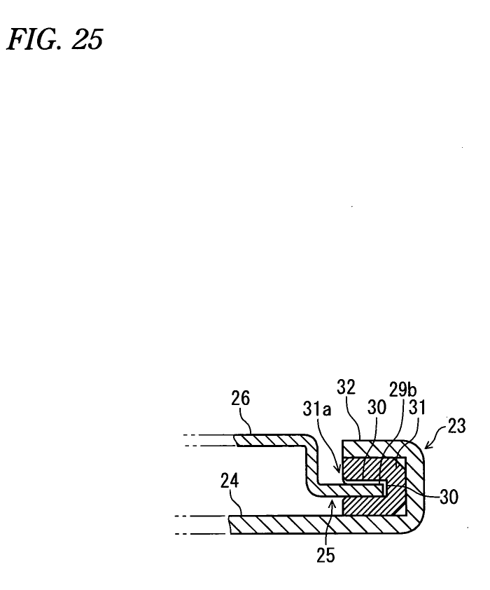

In this embodiment, concave portions 30 are formed not only on the concave sliding surface 28a where the above-mentioned convex end sliding surface 29a slides but also on a sliding surface 28b of the concave guide rail portion 23 with which a convex side end sliding surface 29b positioned at the side end of the convex slide portion 25 comes into pressure contact and slides with the biasing force of the biasing body 27 as shown in FIGS. 22 to 25, as portions where concave portions 30 of the frictional resistance reducing member are formed.

In this embodiment, a concave portion 30 is formed on an upper sliding surface 28b on which the convex side end sliding surface 29b as an upper end of the convex side end sliding surfaces 29b positioned on and beneath the convex slide portion 25 slides. Meanwhile, the concave portion may be formed even on a lower sliding surface 28b on which the convex side end sliding surface 29b as a lower end slides, or may be formed only on the lower sliding surface 28b.

Other structure is the same as that of the first embodiment of the second invention.

Further, like in the case of the first invention, in the embodiments of the second invention, the slide surface of the pressed slide part is formed into a surface, which is smooth in the slide direction, by a cutting apparatus or a polishing apparatus after pressing. According to the cutting or polishing, it may be possible to avoid the inhibition of the above-mentioned smooth slide and to obtain predetermined dimensions as described above. Therefore, it may be possible to obtain an advantage of improving dimensional accuracy.

Meanwhile, the second invention is not limited to the first and second embodiments, and the design of the specific structure of each component may be modified appropriately.

### INDUSTRIAL APPLICABILITY

The invention is suitable for a slide device for a small-sized electronic device, a mobile phone using the slide device, and the like.

1. A slide device comprising:
a first member including a slide guide portion;
a second member including a slide part slidably engaged between the slide guide portion so that the second member is slidable relative to the first member; and
a protrusion formed on the slide guide portion, a slide surface of the slide part, or a portion other than the slide guide portion and the slide surface of the slide part determining a position of the slide surface, said protrusion having a height so that the slide part is not slidably engaged between the slide guide portion, said slide part being slidably engaged between the slide guide portions by crushing the protrusion to a predetermined height.

2. The slide device according to claim 1, wherein said protrusion is formed on the slide guide portion, a slide surface of a component of the slide part, or on a portion other than the slide surface of the component positioned between the component and determining the position of the slide surface, said protrusion having the height so that the slide part is not slidably engaged between the slide guide portion.

3. The slide device according to claim 1, wherein said protrusion is crushed to a height where the slide part is slidably engaged between the slide guide portion.

4. The slide device according to claim 1, wherein said protrusion is formed on at least both end portions of a slide range of the slide part with respect to the slide guide portion.

5. The slide device according to claim 1, wherein said protrusion has a shape protruding in a curved shape.

6. A device comprising the slide device according to claim 1; a main body; and an overlapping part disposed to overlap with the main body, said main body being connected to the overlapping part with the slide device so that the overlapping part slides relatively in a direction of an overlapping surface from a state where the main body overlaps with the overlapping part to expose a part of the overlapping surface, said main body being formed of one of the first member and the second member, said overlapping part being formed of the other of the first member and the second member.

7. A slide device comprising:
a first member;
a second member slidably connected to the first member to overlap with the first member;
a guide rail portion provided on one of the first member and the second member;
a slide portion provided on the other of the first member and the second member to relatively move along the guide rail portion;
a biasing body disposed between the first member and the second member, said biasing body having one end connected to the first member and the other end connected to the second member for biasing the second member relative to the first member in a slide direction; and
a frictional resistance reducing member including a concave portion formed on at least one of a sliding surface of the guide rail portion and a sliding surface of the slide portion, said concave portion being disposed to not contact with the other of the sliding surfaces being pressed against with each other with a biasing force of the biasing body when the first member moves relative to the second member in the slide direction through the biasing force of the biasing body so that the frictional resistance reducing member reduces a contact area between the sliding surfaces to reduce a frictional resistance.

8. The slide device according to claim 7, wherein said guide rail portion has a concave shape or a convex shape formed on the one of the first member and the second member, said slide portion having a convex shape or a concave shape engaged with the guide rail portion one the other of the second member and the first member, said frictional resistance reducing member including the concave portion on at least one of a convex end sliding surface positioned at an end of the slide portion or the guide rail portion with the convex shape and a concave sliding surface of the guide rail portion or the slide portion with the concave shape sliding against the convex end sliding surface with the biasing force of the biasing body, said concave portion being disposed to not contact with the other of the convex end sliding surface and the concave sliding surface.

9. The slide device according to claim 7, wherein said guide rail portion has a concave shape or a convex shape formed on the one of the first member and the second member, said slide portion having a convex shape or a concave shape engaged with the guide rail portion on the other of the second member and the first member, said frictional resistance reducing member including the concave portion on at least one of a convex side end sliding surface positioned at a side end of the slide portion or the guide rail portion with the convex shape and a concave sliding surface of the guide rail portion or the slide portion with the concave shape sliding against the convex end sliding surface with the biasing force of the biasing body, said concave portion being disposed to not contact with the other of the convex side end sliding surface and the concave sliding surface.

10. The slide device according to claim 7, wherein said guide rail portion or said slide portion with the concave shape includes a U-shaped body having a groove at an end portion of a first connection body formed of a plate connected to the first member or the second member, said slide portion or said guide rail portion with the convex shape being engaged with the guide rail portion or the slide portion with the concave shape and including an end portion of a second connection body formed of a plate connected to the second member or the first member, said frictional resistance reducing member including the concave portion on an inner surface of the groove of the U-shaped body.

11. The slide device according to claim 7, wherein said guide rail portion or said slide portion with the concave shape includes the U-shaped body at left and right bent end portions of the first connection body formed of the plate connected to the first member or the second member, said slide portion or said guide rail portion with the convex shape being engaged with the guide rail portion or the slide portion with the concave shape and including right and left end portions of a second connection body formed of a plate connected to the second member or the first member, said frictional resistance reducing member including the concave portion on the inner surface of the groove of the U-shaped body where the slide portion or the guide rail portion with the convex shape slides against with the biasing force of the biasing body.

12. The slide device according to claim 10, wherein the U-shaped body is made of a synthetic resin.

13. The slide device according to claim 7, further comprising a sliding portion on the one of the sliding surfaces where the concave portion is disposed at predetermined both front and rear end positions of the one of the sliding surfaces in the sliding direction for sliding against the other of the sliding surfaces.

14. The slide device according to claim 7, wherein said concave portion is arranged at a plurality of positions with a predetermined interval on at least one of the sliding surfaces of the guide rail portion and the slide portion.

15. An electronic device comprising the slide device according to claim 7; a main body including an operation portion; and an overlapping part including a display, said main body and said overlapping part being disposed to overlap with each other so that the operation portion is covered during a non-operation of the operation portion, said overlapping part sliding substantially parallel and relative to an overlapping surface from a state where the main body and the overlapping part overlap with each other so that the operation portion is exposed, said main body being formed of one of the first member and the second member, said overlapping part being formed of the other of the first member and the second member.
